(19) United States
(12) Patent Application Publication
(10) Pub. No.: US 2020/0267837 A1
(43) Pub. Date: Aug. 20, 2020

(54) CONNECTION SUBSTRATE AND DISPLAY DEVICE INCLUDING THE SAME AND PAD CONTACT RESISTANCE MEASUREMENT METHOD

(71) Applicant: Samsung Display Co., Ltd., Yongin-Si (KR)

(72) Inventors: Seunghwan CHEONG, Hwaseong-si (KR); Ahyoung SON, Seoul (KR); Chanyoon WOO, Cheonan-si (KR)

(21) Appl. No.: 16/682,282

(22) Filed: Nov. 13, 2019

(30) Foreign Application Priority Data
Feb. 18, 2019 (KR) 10-2019-0018636

(51) Int. Cl. H05K 1/14; H01R 12/52; H05K 1/11; G01R 31/04

(52) U.S. Cl. CPC H05K 1/147; H01R 12/52; H05K 2201/10128; G01R 31/046; H05K 1/118

(57) ABSTRACT

A connection substrate includes a first substrate including first and second upper pads, and an inner wire electrically connecting the first and second upper pads, and a second substrate including first and second lower pads connected to the first and second upper pads, respectively. The second substrate includes a first test point disposed at an end of a first test wire extending from the first lower pad, a second test point disposed at an end of a second test wire extending from the second lower pad, and a dummy test point disposed at an end of a dummy test wire branched from a predetermined position of the second test wire and extended. A length of the dummy test wire is determined such that a resistance value of the dummy test wire is equal to a resistance value of the first test wire.

This application claims priority to Korean Patent Application No. 10-2019-0018636, filed on Feb. 18, 2019, and all the benefits accruing therefrom under 35 U.S.C. § 119, the content of which in its entirety is herein incorporated by reference.

### BACKGROUND

### 1. Field

Exemplary embodiments of the invention herein relate to a display device, and more particularly to a display device including a connection substrate electrically connected to a display panel.

### 2. Description of the Related Art

Among display devices, an organic light emitting display device displays an image using an organic light emitting diode (“OLED”) that generates light by recombination of electrons and holes. The organic light emitting display device is advantageous in that it has a substantially fast response speed and is driven with substantially low power consumption.

The organic light emitting display may include a display panel for displaying an image, a host device for providing control signals and image signals for controlling an operation of the display panel, and a connection substrate for providing control signals from the host device and image signals to the display panel.

The connection substrate may include a plurality of circuit substrates, and the circuit substrates may be interconnected through pads. The pads of the circuit substrates are desired to be sufficiently and fully connected so that the control signals and the image signals may be transmitted to the display panel without distortion.

### SUMMARY

Exemplary embodiments of the invention provide a connection substrate capable of checking the connection state of pads of circuit substrates and a display device including the same.

Exemplary embodiments of the invention also provide a contact resistance measurement method of a display device capable of checking the connection state of pads of circuit substrates.

An exemplary embodiment of the invention provides a connection substrate including a first substrate including a first upper pad, a second upper pad, and a first inner wire electrically connecting the first upper pad and the second upper pad, and a second substrate including a first lower pad and a second lower pad connected to the first upper pad and the second upper pad, respectively, a first test point disposed at an end of a first test wire extending from the first lower pad, a second test point disposed at an end of a second test wire extending from the second lower pad, and a first dummy test point disposed at an end of a first dummy test wire branched from a predetermined position of the second test wire and extended, wherein a length of the first dummy test wire is determined such that a resistance value of the first dummy test wire is equal to a resistance value of the first test wire.

In an exemplary embodiment, a difference between a first resistance value between the first test point and the second test point and a second resistance value between the second test point and the first dummy test point may be substantially equal to a sum of a contact resistance value between the first upper pad and the first lower pad and a contact resistance value between the second upper pad and the second lower pad.

In an exemplary embodiment, the first substrate may be composed of a chip-on film on which an integrated circuit is disposed.

In an exemplary embodiment, the first substrate may further include a plurality of upper signal pads, wherein the second substrate may further include a plurality of lower signal pads connected to the plurality of upper signal pads, wherein at least one of the plurality of upper signal pads and the plurality of lower signal pads may be an image signal pad for transmitting an image signal.

In an exemplary embodiment, the first upper pad and the second upper pad may be arranged on one side of the plurality of upper signal pads, and the first lower pad and the second lower pad may be arranged on one side of the plurality of lower signal pads.

In an exemplary embodiment, the second substrate may include a flexible printed circuit substrate including a plurality of signal wires connected to the plurality of lower signal pads.

In an exemplary embodiment, the first substrate may further include a third upper pad, a fourth upper pad, and a second inner wire electrically connecting the third upper pad and the second upper pad, wherein the second substrate may include a third lower pad and a fourth lower pad connected to the third upper pad and the fourth upper pad, respectively, wherein the second substrate may include a third test point disposed at an end of a third test wire extending from the third lower pad, a fourth test point disposed at an end of a fourth test wire extending from the fourth lower pad, and a second dummy test point disposed at an end of a second dummy test wire branched from a predetermined position of the fourth test wire and extended, wherein a length of the second dummy test wire may be determined such that a resistance value of the second dummy test wire is equal to a resistance value of the third test wire.

In an exemplary embodiment, the third upper pad and the fourth upper pad may be arranged on the other side of the plurality of upper signal pads, and the third lower pad and the fourth lower pad may be arranged on the other side of the plurality of lower signal pads.

In an exemplary embodiment, a difference between a resistance value between the third test point and the fourth test point and a resistance value between the fourth test point and the second dummy test point may be substantially equal to a sum of a contact resistance value between the third upper pad and the third lower pad and a contact resistance value between the fourth upper pad and the fourth lower pad.

In an exemplary embodiment, the first substrate may be electrically connected to a display panel.

In an exemplary embodiment of the invention, a display device includes a display panel including a first panel pad, a second panel pad, and a first inner wire electrically connecting the first panel pad and the second panel pad, a first substrate including a first panel connection pad and a second panel connection pad connected to the first panel pad and the second panel pad, respectively, a first upper pad, a second upper pad, a third upper pad, a second inner wire electrically connecting the first upper pad and the second upper pad, a first connection wire for electrically connecting the first panel connection pad and the second inner wire, and a second connection wire electrically connecting the second panel connection pad and the third upper pad, and a second substrate including a first lower pad, a second lower pad, and a third lower pad connected to the first upper pad, the second upper pad, and the third upper pad, respectively, wherein the second substrate includes a first test point disposed at an end of a first test wire extending from the first lower pad, a second test point disposed at an end of a second test wire extending from the second lower pad, a third test point disposed at an end of a third test wire extending from the third lower pad, and a dummy test point disposed at an end of a dummy test wire branched from a predetermined position of the second test wire and extended, wherein a length of the dummy test wire is determined such that a resistance value of the dummy test wire is equal to a resistance value of the third test wire.

In an exemplary embodiment, a difference between a first resistance value between the second test point and the third test point and a second resistance value between the first test point and the second test point may be substantially equal to a sum of a contact resistance value between the first panel pad and the first panel connection pad and a contact resistance value between the first panel pad and the second panel connection pad.

In an exemplary embodiment, a resistance value of the first test wire and the resistance value of the third test wire may be substantially equal.

In an exemplary embodiment, the display panel may further include a plurality of panel signal pads, wherein the first substrate may further include a plurality of panel connection signal pads connected to the plurality of panel signal pads, wherein at least one of the plurality of panel signal pads and the plurality of panel connection signal pads may be an image signal pad which transmits an image signal.

In an exemplary embodiment, the first panel pad and the second panel pad may be arranged on a side of the plurality of panel signal pads, and the first panel connection pad and the second panel connection pad may be arranged on a side of the plurality of panel connection signal pads.

In an exemplary embodiment, the first substrate may further include a plurality of upper signal pads, wherein the second substrate may further include a plurality of lower signal pads connected to the plurality of upper signal pads, wherein at least one of the plurality of upper signal pads and the plurality of lower signal pads may be an image signal pad for transmitting an image signal.

In an exemplary embodiment, the first upper pad, the second upper pad, and the third upper pad may be arranged on one side of the plurality of upper signal pads, and the first lower pad, the second lower pad, and the third lower pad may be arranged on one side of the plurality of lower signal pads.

In an exemplary embodiment, when the display panel and the first substrate are not connected to each other, a difference between a first resistance value between the first test point and the second test point and a second resistance value between the second test point and the dummy test point may be substantially equal to a sum of a contact resistance value between the first upper pad and the first lower pad and a contact resistance value between the second upper pad and the second lower pad.

An exemplary embodiment of the invention provides a method of measuring a pad contact resistance of a display device including a first substrate including a first upper pad and a second upper pad and a second substrate including a first lower pad and a second lower pad. The method includes connecting the first upper pad and the first lower pad, and connecting the second upper pad and the second lower pad, measuring a first resistance value between a first test point disposed at an end of a first test wire extending from the first lower pad and a second test point disposed at an end of a second test wire extending from the second lower pad, measuring a second resistance value between the second test point and a dummy test point disposed at an end of a dummy test wire branched from a predetermined position of the second test wire and extended, and calculating a first contact resistance value between the first upper pad and the first lower pad and a second contact resistance value between the second upper pad and the second lower pad based on a difference value between the first resistance value and the second resistance value.

In an exemplary embodiment, a length of the dummy test wire may be determined such that a resistance value of the dummy test wire is equal to a resistance value of the first test wire.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a perspective view of an exemplary embodiment of a display device according to the invention;

FIG. 2 is a plan view illustrating an exemplary embodiment of a display device according to the invention;

FIG. 3 is a cross-sectional view illustrating an exemplary embodiment of a connection between a display panel and a connection substrate according to the invention;

FIG. 4 is a plan view of an exemplary embodiment of a connection substrate according to the invention; and

FIG. 5 is a plan view of an exemplary embodiment of a display panel and a connection substrate according to the invention.

### DETAILED DESCRIPTION

In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description.

“And/or” includes all of one or more combinations defined by related components.

It will be understood that the terms “first” and “second” are used herein to describe various components but these components should not be limited by these terms. The above terms are used only to distinguish one component from another. For example, a first component may be referred to as a second component and vice versa without departing from the scope of the invention. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawing.

Unless otherwise defined, all terms (including technical and scientific terms) used herein have the same meaning as terms commonly understood by those skilled in the art to which this invention belongs. In general, the terms defined in the dictionary should be considered to have the same meaning as the contextual meaning of the related art, and, unless clearly defined herein, should not be understood abnormally or as having an excessively formal meaning.

In various exemplary embodiments of the invention, the term “include,” “comprise,” “including,” or “comprising,” specifies a property, a region, a fixed number, a step, a process, an element and/or a component but does not exclude other properties, regions, fixed numbers, steps, processes, elements and/or components.

Hereinafter, another exemplary embodiment of the invention will be described with reference to the drawings.

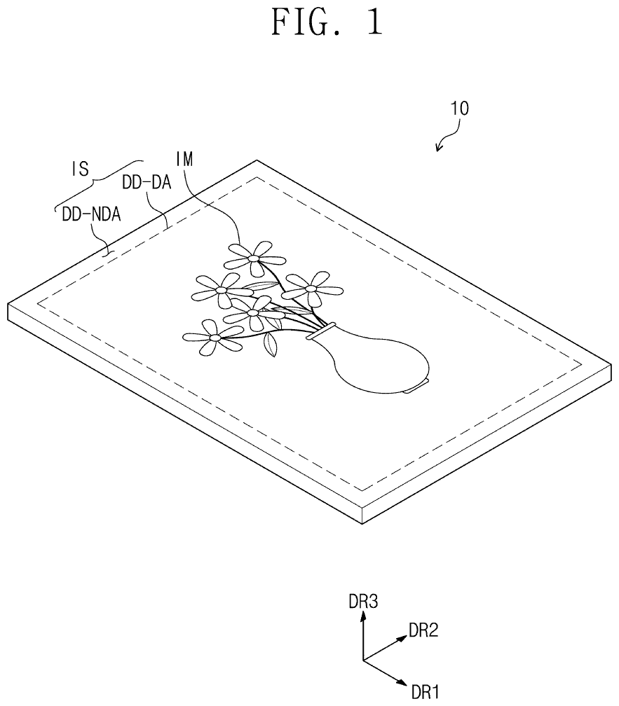

FIG. 1 is a perspective view of an exemplary embodiment of a display device according to the invention.

Referring to FIG. 1, an exemplary embodiment of the display device 10 may be a liquid crystal display device, a field emission display device, a plasma display device, or an organic light emitting display device, for example. However, those are exemplarily listed, and the display device 10 is not limited to the types of display devices listed above.

In FIG. 1, a flat panel display device is shown as an example of the display device 10. However, the invention is not limited to this, and the display device 10 may be a deformable device such as a foldable display device, a rollable display device, or a banded display device, and is not particularly limited. The display device 10 may be used for small and medium-sized electronic devices such as mobile phones, tablets, car navigations, game consoles, and smart watches in addition to large-sized electronic devices such as televisions and monitors.

An exemplary embodiment of the display device 10 includes a display surface IS where an image IM is displayed, which is parallel to a surface that a first direction DR1 and a second direction DR2 define. In an exemplary embodiment, a third direction DR3 may be a direction perpendicular to both the first direction DR1 and the second direction DR2. The display device 10 may include a plurality of areas. The display device 10 may include a display area DD-DA where an image IM is displayed and a non-display area DD-NDA adjacent to the display area DD-DA. The non-display area DD-NDA is an area for displaying no image.

FIG. 1 illustrates a vase as one example of the image IM. As one example, the display area DD-DA may have a rectangular form. The non-display area DD-NDA may surround the display area DD-DA. However, the invention is not limited thereto, and a form of the display area DD-DA and a form of the non-display area DD-NDA may be designed relatively.

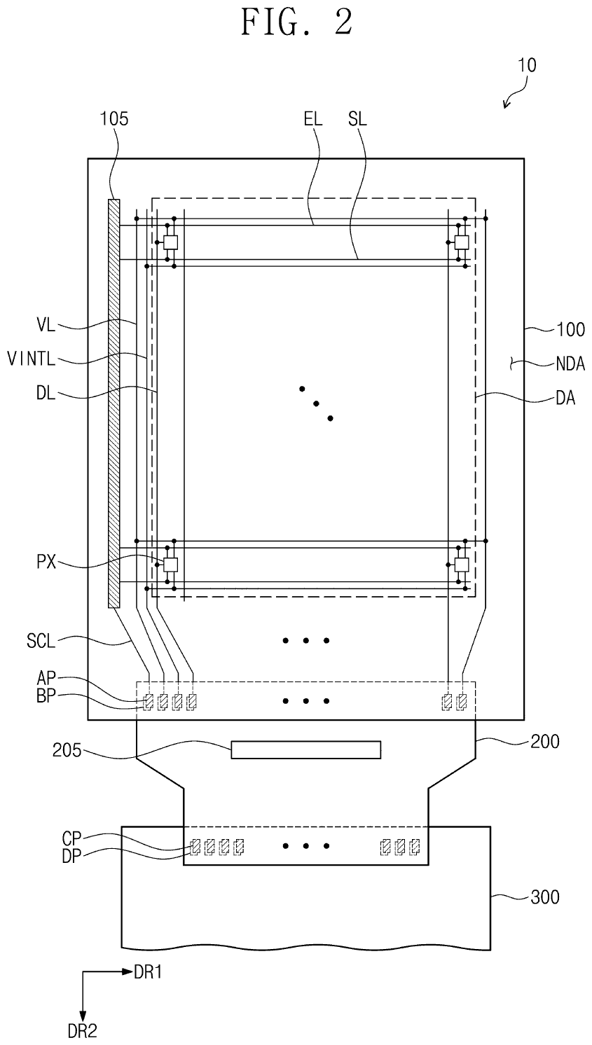

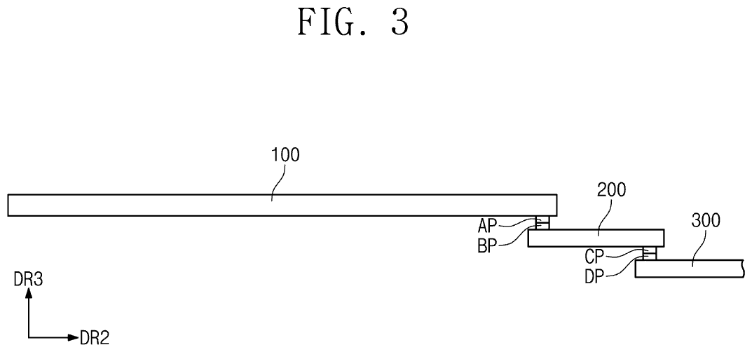

FIG. 2 is a plan view illustrating an exemplary embodiment of a display device according to the invention. FIG. 3 is a cross-sectional view illustrating an exemplary embodiment of a connection between a display panel and a connection substrate according to the invention.

Referring to FIGS. 2 and 3, an exemplary embodiment of the display device 10 includes a display panel 100, a first substrate 200, and a second substrate 300.

The display panel 100 includes a display area DA and a non-display area NDA in a plan view. The display area DA and the non-display area NDA of the display panel 100 correspond to the display area DD-DA (refer to FIG. 1) and the non-display area DD-NDA (refer to FIG. 1) of the display device 10, respectively. The display area DA and the non-display area NDA of the display panel 100 are not necessarily the same as the display area DD-DA (refer to FIG. 1) and the non-display area DD-NDA (refer to FIG. 1) of the display device 10, and may be changed according to the structure and/or design of the display panel 100.

The display panel 100 includes a plurality of pixels PX. An area where the plurality of pixels PX is disposed may be defined as the display area DA. In this exemplary embodiment, the non-display area NDA may be defined along the outline of the display area DA.

Referring to FIG. 2, the display panel 100 includes scan lines SL, data lines DL, light emitting lines EL, a scan control line SCL, an initialization voltage line VINTL, and voltage line VL.

The scan driving circuit 105 connected to the scan lines SL and the light emitting lines EL may be disposed on one side of the non-display area NDA.

The scan lines SL extend from the scan driving circuit 105 in the first direction DR1 and are connected to the corresponding pixels PX of the plurality of pixels PX, respectively. Each of the light emitting lines EL may extend from the scan driving circuit 105 in the first direction DR1 and may be arranged in parallel to the corresponding one of the scan lines SL. The data lines DL extend in the second direction DR2 and are connected to the corresponding pixels PX of the plurality of pixels PX, respectively. The scan control line SCL may provide control signals to the scan driving circuit 105. The initialization voltage line VINTL may provide an initialization voltage to the plurality of pixels PX. The voltage line VL may be connected to the plurality of pixels PX and provide a first voltage to the plurality of pixels PX. The voltage line VL may include a plurality of lines extending in the first direction DR1 and a plurality of lines extending in the second direction DR2.

Some of the scan lines SL, the data lines DL, the light emitting lines EL, the scan control line SCL, the initializing voltage line VINTL, and the voltage line VL are disposed on the same layer, and some of them may be disposed on a different layer.

In the non-display area NDA of the display panel 100, the panel pads AP are arranged. The panel pads AP may be arranged side by side in the first direction DR1. In this exemplary embodiment, the panel pads AP are shown and described as being arranged in a line in the first direction DR1, but are not limited thereto. In an exemplary embodiment, the panel pads AP may be arranged in two or more rows, or arranged in a zigzag pattern, for example.

The data lines DL, the scan control line SCL, the initialization voltage line VINTL and the voltage line VL are connected to the panel pads AP.

The panel pads AP of the display panel 100 may be connected to the panel connection pads BP of the first substrate 200. The first substrate 200 may be a flexible circuit substrate on which an integrated circuit (“IC”) 205 may be disposed (e.g., mounted). In an exemplary embodiment, the first substrate 200 may be a chip on film (“COF”), for example. Although only one IC 205 is disposed (e.g., mounted) on the first substrate 200 of FIG. 2, in another exemplary embodiment, a plurality of ICs may be disposed (e.g., mounted) on the first substrate 200. In an exemplary embodiment, the IC 205 may include a drive controller, a data driver, a voltage generator, and the like, for example.

Although not shown in the drawings, a plurality of wires for electrically connecting the panel pads AP of the display panel 100 to the IC 205 may be arranged on the first substrate 200.

The panel pads AP may be arranged on the lower surface of the display panel 100 and the panel connection pads BP may be arranged on the upper surface of the first substrate 200. When the panel pads AP and the panel connection pads BP are connected, the panel pads AP and the panel connection pads BP are not visible from the upper surface of the display panel 100. Therefore, in FIG. 2, the panel pads AP and the panel connection pads BP are indicated by dotted lines. In another exemplary embodiment, the panel pads AP may be arranged on the upper surface of the display panel 100, and the panel connection pads BP may be arranged on the lower surface of the first substrate 200. In this case, when the panel pads AP and the panel connection pads BP are connected, a predetermined area of the first substrate 200 overlaps with a portion of the upper side of the display panel 100.

The first substrate 200 further includes upper pads CP. The second substrate 300 includes lower pads DP. In this exemplary embodiment, the upper pads CP are arranged on the lower surface of the first substrate 200 and the lower pads DP are arranged on the upper surface of the second substrate 300. The upper pads CP of the first substrate 200 may be connected to the lower pads DP of the second substrate 300. In this exemplary embodiment, it will be understood that the upper pad and the lower pad are defined terms for convenience of description and are not intended to limit the scope of the invention. In another exemplary embodiment, the upper pads CP may be arranged on the upper surface of the first substrate 200 and the lower pads DP may be arranged on the lower surface of the second substrate 300. In this case, when the upper pads CP and the lower pads DP are connected, a predetermined area of the second substrate 300 overlaps with a portion of the upper side of the first substrate 200.

The second substrate 300 may further include signal wires (not shown) for transferring control signals and image signals received from a host device (not shown) to the lower pads DP. The second substrate 300 may be a flexible printed circuit (“FPC”) substrate.

To help understand the connection of panel pads AP and panel connection pads BP, the panel pads AP and the panel connection pads BP are shown misaligned but it is preferable that the panel pads AP and the panel connection pads BP are sufficiently and fully connected.

The panel pads AP and the panel connection pads BP are desired to be sufficiently and fully connected so that control signals and image signals from the IC 205 may be transmitted to the display panel 100 without distortion.

In the same manner, to help understand the connection of the upper pads CP and the lower pads DP, the upper pads CP and the lower pads DP are shown misaligned but it is preferable that the upper pads CP and the lower pads DP are sufficiently and fully connected.

The upper pads CP and the lower pads DP are desired to be sufficiently and fully connected so that control signals and image signals received from the host device (not shown) may be transmitted to the IC 205 without distortion.

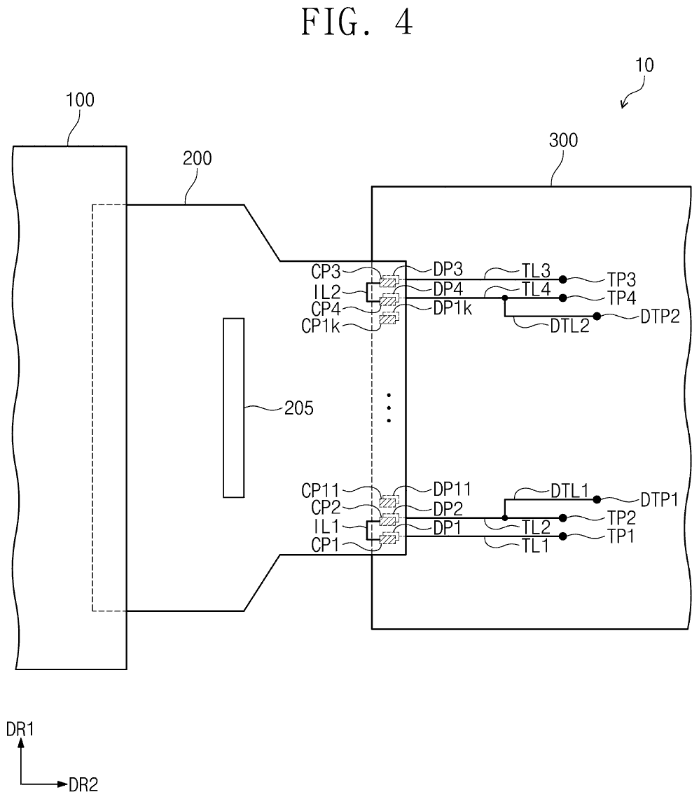

FIG. 4 is a plan view of an exemplary embodiment of a connection substrate according to the invention.

Referring to FIG. 4, the first substrate 200 includes first to fourth upper pads CP1, CP2, CP3, and CP4 and upper signal pads CP11 to CP1k. The first to fourth upper pads CP1, CP2, CP3 and CP4 and the upper signal pads CP11 to CP1k shown in FIG. 4 correspond to the upper pads CP shown in FIG. 2. The first substrate 200 further includes a first inner wire IL1 and a second inner wire IL2. The first inner wire IL1 electrically connects the first upper pad CP1 and the second upper pad CP2, and the second inner wire IL2 electrically connects the third upper pad CP3 and the fourth upper pad CP4.

The first to fourth upper pads CP1, CP2, CP3 and CP4 are test pads for testing the contact state between the first substrate 200 and the second substrate 300, and the upper signal pads CP11 to CP1k are signal pads for transmitting control signals and image signals.

The first upper pad CP1 and the second upper pad CP2 are arranged on one side (e.g., lower side in FIG. 4) of the upper signal pads CP11 to CP1k, and the third upper pad CP3 and the fourth upper pad CP4 are arranged on the other side (e.g., upper side in FIG. 4) of the upper signal pads CP11 to CP1k.

The second substrate 300 includes first to fourth lower pads DP1, DP2, DP3 and DP4 and lower signal pads DP11 to DP1k. The first to fourth lower pads DP1, DP2, DP3 and DP4 and the lower signal pads DP11 to DP1k shown in FIG. 4 correspond to the lower pads DP shown in FIG. 2.

The first to fourth lower pads DP1, DP2, DP3, and DP4 are test pads for testing the contact state between the first substrate 200 and the second substrate 300, and the lower signal pads DP11 to DP1k are signal pads for transmitting control signals and image signals.

The first lower pad DP1 and the second lower pad DP2 are arranged on one side (e.g., lower side in FIG. 4) of the lower signal pads DP11 to DP1k, and the third lower pad DP3 and the fourth lower pad DP4 are arranged on the other side e.g., upper side in FIG. 4) of the lower signal pads DP11 to DP1k.

The second substrate 300 includes first to fourth test wires TL1, TL2, TL3, and TL4 respectively extending from the first to fourth lower pads DP1, DP2, DP3, and DP4, and first to fourth test points TP1, TP2, TP3, and TP4. One end of each of the first to fourth test wires TL1, TL2, TL3 and TL4 is connected to a corresponding one of the first to fourth lower pads DP1, DP2, DP3 and DP4. The other end of each of the first to fourth test wires TL1, TL2, TL3 and TL4 is connected to a corresponding one of the first to fourth test points TP1, TP2, TP3 and TP4.

One end (e.g., left end in FIG. 4) of the first dummy test wire DTL1 is connected to the second test wire TL2 such that the first dummy test wire DTL1 is branched from the second test wire TL2 and the other end (e.g., right end in FIG. 4) of the first dummy test wire DTL1 is connected to the first dummy test point DTP1.

In an exemplary embodiment, the length of the first dummy test wire DTL1 may be determined such that the resistance value of the first dummy test wire DTL1 is equal to the resistance value of the first test wire TL1. Here, the resistance value of the first dummy test wire DTL1 is the resistance value between the point starting to be branched from the second test wire TL2 and the first dummy test point DTP1. The resistance value of the second test wire TL2 is the resistance value between the point where connection with the second lower pad DP2 ends and the second test point TP2.

In addition, the first test wire TL1 and the first dummy test wire DTL1 include the same material, and have the same width, length, and thickness such that it is assumed that the first test wire TL1 and the first dummy test wire DTL1 have the same resistance value.

When the resistance value between the first test point TP1 and the second test point TP2 is measured using a test probe or the like, the first resistance value (Rtp1×tp2) on the signal path provided through the first test wire TL1, the first lower pad DP1, the first upper pad CP1, the first inner wire ILL the second upper pad CP2, the second lower pad DP2, and the second test wire TL2 may be known.

When the resistance value between the second test point TP2 and the first dummy test point DTP1 is measured using a test probe or the like, the second resistance value (Rtp2×tp1) on the signal path provided through the second test wire TL2 and the first dummy test wire DTL1 may be known.

When it is assumed that the resistance value of the first inner wire IL1 is very small, the sum of the first contact resistance value Rc1 between the first upper pad CP1 and the first lower pad DP1 and the second contact resistance value Rc2 between the second upper pad CP2 and the second lower pad DP2 is expressed by Equation 1.

Rc1+Rc2=Rtp1×tp2−Rtp2×tp1 [Equation 1]

The first average resistance value Rca, which is an average value of the first contact resistance value Rc1 and the second contact resistance value Rc2, is expressed by Equation 2.

Rca=(Rtp1×p2−Rtp2×tp1)/2 [Equation 2]

In an exemplary embodiment, when the first resistance value (Rtp1×p2) between the first test point TP1 and the second test point TP2 is 1 ohm (S2) and the second resistance value (Rtp2×tp1) between the second test point TP2 and the first dummy test point DTP1 is 0.7Ω, the sum of the first contact resistance value Rc1 between the first upper pad CP1 and the first lower pad DP1 and the second contact resistance value Rc2 between the second upper pad CP2 and the second lower pad DP2 is 0.3Ω, for example.

In such a manner, the contact resistance between any one of the upper pads CP and any one of the lower pads DP may be known in an easy way by measuring the resistance twice.

In an exemplary embodiment, the length of the second dummy test wire DTL2 may be determined such that the resistance value DR2 of the second dummy test wire DTL2 is equal to the resistance value R3 of the third test wire TL3.

In addition, the third test wire TL3 and the second dummy test wire DTL2 include the same material, and have the same width, length, and thickness such that it is assumed that the third test wire TL3 and the second dummy test wire DTL2 have the same resistance value.

When the resistance value between the third test point TP3 and the fourth test point TP4 is measured using a test probe or the like, the third resistance value (Rtp3×p4) on the signal path provided through the third test wire TL3, the third lower pad DP3, the third upper pad CP3, the second inner wire IL2, the fourth upper pad CP4, the fourth lower pad DP4, and the fourth test wire TL4 may be known.

When the resistance value between the fourth test point TP4 and the second dummy test point DTP2 is measured using a test probe or the like, the fourth resistance value (Rtp4×tp2) on the signal path provided through the fourth test wire TL4 and the second dummy test wire DTL2 may be known.

The sum of the third contact resistance value Rc3 between the third upper pad CP3 and the third lower pad DP3 and the fourth contact resistance value Rc4 between the fourth upper pad CP4 and the fourth lower pad DP4 is expressed by Equation 3.

Rc3+Rc4=Rtp3×p4−Rtp4×tp2 [Equation 3]

The second average resistance value Rcb of the third contact resistance value Rc3 and the fourth contact resistance value Rc4 is expressed by Equation 4.

Rcb=(Rtp3×p4−Rtp4×tp2)/2 [Equation 4]

When the difference value between each of the first average resistance value Rca and the second average resistance value Rcb and the reference value is out of the error range, it may be determined that the first substrate 200 and the second substrate 300 are not normally connected.

As another example, when the difference value between the first average resistance value Rca and the second average resistance value Rcb is out of the error range, it may be determined that the first substrate 200 and the second substrate 300 are not normally connected.

In an exemplary embodiment, it is exemplarily shown and described that a first upper pad CP1 and a second upper pad CP2 are arranged on one side of the upper signal pads CP11 through CP1k, and a first lower pad DP1 and a second lower pad DP2 are arranged on one side of the lower signal pads DP11 to DP1k, and a third upper pad CP3 and a fourth upper pad CP4 are arranged on the other side of the upper signal pads CP11 to CP1k, and a third lower pad DP3 and a fourth lower pad DP4 are arranged on the other side of the lower signal pads DP11 to DP1k. However, the invention is not limited thereto.

In another exemplary embodiment, the upper signal pads and the lower signal pads may be arranged only on one side of the upper signal pads CP11 to CP1k and the lower signal pads DP11 to DP1k, for example.

In another exemplary embodiment, the number of upper signal pads and lower signal pads arranged on both opposite sides of the upper signal pads CP11 to CP1k and the lower signal pads DP11 to DP1k may be variously changed.

By arranging the upper signal pads and the lower signal pads on both opposite sides of the upper signal pads CP11 to CP1k and the lower signal pads DP11 to DP1k, it does not affect the signal wire connected to the upper signal pads CP11 to CP and the lower signal pads DP11 to DP1k.

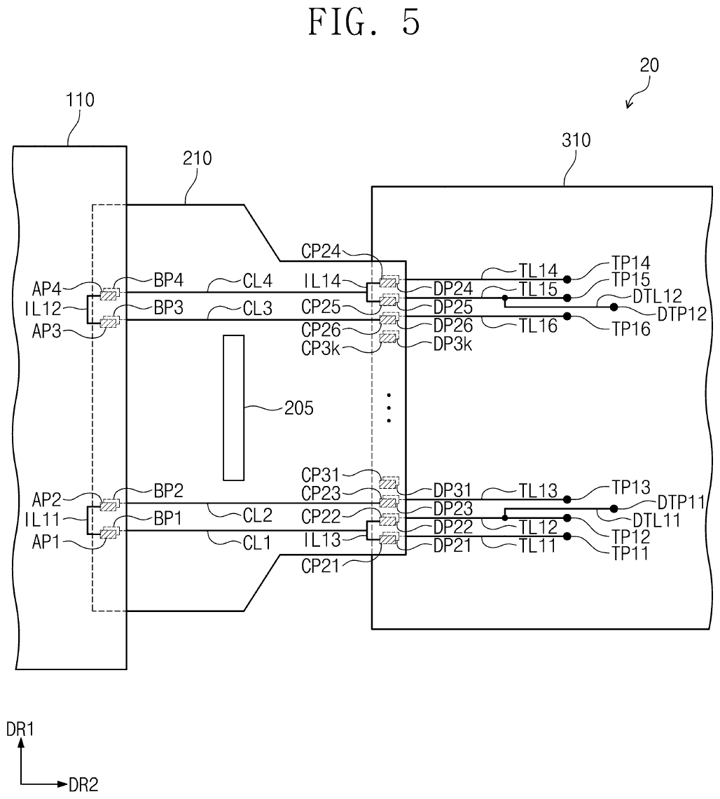

FIG. 5 is a plan view of an exemplary embodiment of a display panel and a connection substrate according to the invention.

Referring to FIG. 5, the display device 20 may include a display panel 110, a first substrate 210, and a second substrate 310.

The display panel 110 includes first to fourth panel pads AP1 to AP4, a first inner wire IL11, and a second inner wire IL12. The first inner wire IL11 electrically connects the first panel pad AP1 and the second panel pad AP2. The second inner wire IL12 electrically connects the third panel pad AP3 and the fourth panel pad AP4.

The first substrate 210 includes first to fourth panel connection pads BP1, BP2, BP3, and BP4. The first to fourth panel connection pads BP1, BP2, BP3 and BP4 of the first substrate 210 may be connected to the first to fourth panel pads AP1 to AP4 of the display panel 110, respectively.

The first substrate 210 includes first to sixth upper pads CP21, CP22, CP23, CP24, CP25 and CP26 and upper signal pads CP31 to CP3k. The first substrate 210 further includes a third inner wire IL13 for electrically connecting the first upper pad CP21 and the second upper pad CP22 and a fourth inner wire IL14 for electrically connecting the fourth upper pad CP24 and the fifth upper pad CP25. Also, the first substrate 210 may further include a first connection wire CL1 for electrically connecting the first panel connection pad BP1 and the third inner wire IL13, a second connection wire CL2 for electrically connecting the second panel connection pad BP2 and the third upper pad CP23, a third connection wire CL3 electrically connecting the third panel connection pad BP3 and the sixth upper pad CP26, and a fourth connection wire CL4 electrically connecting the fourth panel connection pad BP4 and the fourth inner wire IL14.

The first to sixth upper pads CP21, CP22, CP23, CP24, CP25, and CP 26 are test pads for testing a contact state between the first substrate 210 and the second substrate 310 and a contact state between the display panel 110 and the first substrate 210. The upper signal pads CP31 to CP3k are signal pads for transmitting control signals and image signals.

The first upper pad CP21, the second upper pad CP22 and the third upper pad CP23 are arranged on one side (e.g., lower side in FIG. 5) of the upper signal pads CP31 to CP3k, and the fourth upper pad CP24, the fifth upper pad CP25 and the sixth upper pad CP26 are arranged on the other side (e.g., upper side in FIG. 5) of the upper signal pads CP31 to CP3k.

The second substrate 310 includes first to sixth lower pads DP21, DP22, DP23, DP24, DP25 and DP26 and lower signal pads DP31 to DP3k. The first to sixth lower pads DP21, DP22, DP23, DP24, DP25, and DP26 are test pads for testing a contact state between the first substrate 210 and the second substrate 310 and a contact state between the display panel 110 and the first substrate 210. The lower signal pads DP31 to DP3k are signal pads for transmitting control signals and image signals.

The first lower pad DP21, the second lower pad DP22 and the third lower pad DP23 are arranged on one side (e.g., lower side in FIG. 5) of the lower signal pads DP31 to DP3k, and the fourth lower pad DP24, the fifth lower pad DP25 and the sixth lower pad DP26 are arranged on the other side (e.g., upper side in FIG. 5) of the lower signal pads DP31 to DP3k.

The second substrate 310 may include the first to sixth test wires TL11, TL12, TL13, TL14, TL15, and TL16 respectively extending from the first to sixth lower pads DP21, DP22, DP23, DP24, DP25, and DP26, and first to sixth test points TP11, TP12, TP13, TP14, TP15, and TP16. One end (e.g., left end in FIG. 5) of each of the first to sixth test wires TL11, TL12, TL13, TL14, TL15 and TL16 is connected to a corresponding one of the first to sixth lower pads DP21, DP22, DP23, DP24, DP25, and DP26. The other end (e.g., right end in FIG. 5) of each of the first to sixth test wires TL11, TL12, TL13, TL14, TL15 and TL16 is connected to a corresponding one of the first to sixth test points TP11, TP12, TP13, TP14, TP15, and TP16.

One end (e.g., left end in FIG. 5) of the first dummy test wire DTL11 is connected to the second test wire TL12 such that the first dummy test wire DTL11 is branched from the second test wire TL12, and the other end (e.g., right end in FIG. 5) of the first dummy test wire DTL11 is connected to the first dummy test point DTP11.

In an exemplary embodiment, the length of the first dummy test wire DTL11 may be determined such that the resistance value of the first dummy test wire DTL11 is equal to the resistance value of the third test wire TL13. Here, the resistance value of the first dummy test wire DTL11 is the resistance value between the point starting to be branched from the second test wire TL12 and the first dummy test point DTP11. The resistance value of the third test wire TL13 is the resistance value between the point where connection with the third lower pad DP23 ends and the third test point TP3.

In addition, the first test wire TL11, the third test wire TL13, and the first dummy test wire DTL11 include the same material, and are have the same length, width, and thickness such that it is assumed that the first test wire TL11, the third test wire TL13, and the first dummy test wire DTL11 have the same resistance value.

When the resistance value between the second test point TP12 and the third test point TP13 is measured using a test probe or the like, the first resistance value (Rtp12×p13) on the signal path provided through the second test wire TL12, the second lower pad DP22, the second upper pad CP22, the third inner wire IL13, the first connection wire CL1, the first panel connection pad BP1, the first panel pad AP1, the first inner wire IL11, the second panel pad AP2, the second panel connection pad BP2, the second connection wire CL2, the third upper pad CP23, the third lower pad DP23, and the third test wire TL13 may be known.

When the resistance value between the second test point TP12 and the first dummy test point DTP11 is measured using a test probe or the like, the second resistance value (Rtp12×tp11) on the signal path provided through the second test wire TL12 and the first dummy test wire DTL11 may be known.

The sum of the first contact resistance value Rc11 between the first panel pad AP1 and the first panel connection pad BP1 and the second contact resistance value Rc12 between the second panel pad AP2 and the second panel connection pad BP2 is expressed by Equation 5.

Rc11+Rc12=Rtp12×p13−Rtp12×tp11−(Rc1+Rc2) [Equation 5]

Rc1 is a first contact resistance value between the first upper pad CP21 and the first lower pad DP21 and Rc2 is a contact resistance value between the second upper pad CP22 and the second lower pad DP22.

When the resistance value between the first test point TP11 and the second test point TP12 is measured, the third resistance value (Rtp11×p12) on the signal path provided through the first test wire TL11, the first lower pad DP21, the first upper pad CP21, the third inner wire IL13, the second upper pad CP22, the second lower pad DP22, and the second test wire TL12 may be known.

Since the first test wire TL11 has the same resistance value as that of the first dummy test wire DTL11, Equation 5 may be modified to Equation 6.

Rc11+Rc12=Rtp12×p13−Rtp11×p12 [Equation 6]

The first average resistance value Rca1, which is an average value of the first contact resistance value Rc11 and the second contact resistance value Rc12, is expressed by Equation 7.

Rca1=(Rtp12×p13−Rtp11×p12)/2 [Equation 7]

That is, when the first resistance value (Rtp12×p13), which is the resistance value between the second test point TP12 and the third test point TP13, is measured and the third resistance value (Rtp11×p12), which is the resistance value between the first test point TP11 and the second test point TP12, is measured using a test probe or the like to calculate the difference value (Rtp12×p13−Rtp11×tp12) and the average value, the average contact resistance value Rca1 of the first and second panel pads AP1 and AP2 of the display panel 110 and the first and second panel connection pads BP1 and BP2 of the first substrate 210 may be known.

Through a similar method, the average contact resistance value Rcb2 of the third and fourth panel pads AP3 and AP4 of the display panel 110 and the third and fourth panel connection pads BP3 and BP4 of the first substrate 210 may be known.

When the difference value between each of the first average resistance value Rca1 and the second average resistance value Rcb2 and the reference value is out of the error range, it may be determined that the display panel 110 and the first substrate 210 are not normally connected.

As another example, when the difference value between the first average resistance value Rca1 and the second average resistance value Rcb2 is out of the error range, it may be determined that the display panel 110 and the first substrate 210 are not normally connected.

The connection substrate having such a configuration may accurately measure the contact resistance between the pads of the first substrate and the pads of the second substrate. Therefore, the connection state between the first substrate and the second substrate may be accurately tested.

Although the exemplary embodiments of the invention have been described, it is understood that the invention should not be limited to these exemplary embodiments but various changes and modifications may be made by one ordinary skilled in the art within the spirit and scope of the invention as hereinafter claimed.

What is claimed is:

1. A connection substrate comprising:
a first substrate comprising a first upper pad, a second upper pad, and a first inner wire electrically connecting the first upper pad and the second upper pad; and
a second substrate comprising:
a first lower pad and a second lower pad connected to the first upper pad and the second upper pad, respectively,
a first test point disposed at an end of a first test wire extending from the first lower pad;
a second test point disposed at an end of a second test wire extending from the second lower pad; and
a first dummy test point disposed at an end of a first dummy test wire branched from a predetermined position of the second test wire and extended,
wherein a length of the first dummy test wire is determined such that a resistance value of the first dummy test wire is equal to a resistance value of the first test wire.

2. The connection substrate of claim 1, wherein a difference between a first resistance value between the first test point and the second test point and a second resistance value between the second test point and the first dummy test point is substantially equal to a sum of a contact resistance value between the first upper pad and the first lower pad and a contact resistance value between the second upper pad and the second lower pad.

3. The connection substrate of claim 1, wherein the first substrate is composed of a chip-on film on which an integrated circuit is disposed.

4. The connection substrate of claim 1, wherein the first substrate further comprises a plurality of upper signal pads,
wherein the second substrate further comprises a plurality of lower signal pads connected to the plurality of upper signal pads,
wherein at least one of the plurality of upper signal pads and the plurality of lower signal pads is an image signal pad which transmits an image signal.

5. The connection substrate of claim 4, wherein the first upper pad and the second upper pad are arranged on a side of the plurality of upper signal pads, and
the first lower pad and the second lower pad are arranged on a side of the plurality of lower signal pads.

6. The connection substrate of claim 4, wherein the second substrate further comprises a flexible printed circuit substrate comprising a plurality of signal wires connected to the plurality of lower signal pads.

7. The connection substrate of claim 4, wherein the first substrate further comprises a third upper pad, a fourth upper pad, and a second inner wire electrically connecting the third upper pad and the second upper pad,
wherein the second substrate further comprises:
a third lower pad and a fourth lower pad connected to the third upper pad and the fourth upper pad, respectively,
a third test point disposed at an end of a third test wire extending from the third lower pad;
a fourth test point disposed at an end of a fourth test wire extending from the fourth lower pad; and
a second dummy test point disposed at an end of a second dummy test wire branched from a predetermined position of the fourth test wire and extended,
wherein a length of the second dummy test wire is determined such that a resistance value of the second dummy test wire is equal to a resistance value of the third test wire.

8. The connection substrate of claim 7, wherein the third upper pad and the fourth upper pad are arranged on a side of the plurality of upper signal pads, and
the third lower pad and the fourth lower pad are arranged on a side of the plurality of lower signal pads.

9. The connection substrate of claim 7, wherein a difference between a resistance value between the third test point and the fourth test point and a resistance value between the fourth test point and the second dummy test point is substantially equal to a sum of a contact resistance value between the third upper pad and the third lower pad and a contact resistance value between the fourth upper pad and the fourth lower pad.

10. The connection substrate of claim 1, wherein the first substrate is electrically connected to a display panel.

11. A display device comprising:
a display panel comprising a first panel pad, a second panel pad, and a first inner wire electrically connecting the first panel pad and the second panel pad;
a first substrate comprising: a first panel connection pad and a second panel connection pad connected to the first panel pad and the second panel pad, respectively; a first upper pad, a second upper pad, a third upper pad, a second inner wire electrically connecting the first upper pad and the second upper pad; a first connection wire for electrically connecting the first panel connection pad and the second inner wire; and a second connection wire electrically connecting the second panel connection pad and the third upper pad; and
a second substrate comprising a first lower pad, a second lower pad, and a third lower pad connected to the first upper pad, the second upper pad, and the third upper pad, respectively,
wherein the second substrate comprises:
a first test point disposed at an end of a first test wire extending from the first lower pad;
a second test point disposed at an end of a second test wire extending from the second lower pad;
a third test point disposed at an end of a third test wire extending from the third lower pad; and
a dummy test point disposed at an end of a dummy test wire branched from a predetermined position of the second test wire and extended,
wherein a length of the dummy test wire is determined such that a resistance value of the dummy test wire is equal to a resistance value of the third test wire.

12. The display device of claim 11, wherein a difference between a first resistance value between the second test point and the third test point and a second resistance value between the first test point and the second test point is substantially equal to a sum of a contact resistance value between the first panel pad and the first panel connection pad and a contact resistance value between the first panel pad and the second panel connection pad.

13. The display device of claim 11, wherein a resistance value of the first test wire and the resistance value of the third test wire are substantially equal.

14. The display device of claim 11, wherein the display panel further comprises a plurality of panel signal pads,
wherein the first substrate further comprises a plurality of panel connection signal pads connected to the plurality of panel signal pads,
wherein at least one of the plurality of panel signal pads and the plurality of panel connection signal pads is an image signal pad which transmits an image signal.

15. The display device of claim 14, wherein the first panel pad and the second panel pad are arranged on a side of the plurality of panel signal pads, and
the first panel connection pad and the second panel connection pad are arranged on a side of the plurality of panel connection signal pads.

16. The display device of claim 11, wherein the first substrate further comprises a plurality of upper signal pads,
wherein the second substrate further comprises a plurality of lower signal pads connected to the plurality of upper signal pads,
wherein at least one of the plurality of upper signal pads and the plurality of lower signal pads is an image signal pad which transmits an image signal.

17. The display device of claim 16, wherein the first upper pad, the second upper pad, and the third upper pad are arranged on a side of the plurality of upper signal pads, and
the first lower pad, the second lower pad, and the third lower pad are arranged on a side of the plurality of lower signal pads.

18. The display device of claim 11, wherein when the display panel and the first substrate are not connected to each other, a difference between a first resistance value between the first test point and the second test point and a second resistance value between the second test point and the dummy test point is substantially equal to a sum of a contact resistance value between the first upper pad and the first lower pad and a contact resistance value between the second upper pad and the second lower pad.

19. A method of measuring a pad contact resistance of a display device comprising a first substrate comprising a first upper pad and a second upper pad and a second substrate comprising a first lower pad and a second lower pad, the method comprising:
connecting the first upper pad and the first lower pad, and connecting the second upper pad and the second lower pad;
measuring a first resistance value between a first test point disposed at an end of a first test wire extending from the first lower pad and a second test point disposed at an end of a second test wire extending from the second lower pad;
measuring a second resistance value between the second test point and a dummy test point disposed at an end of a dummy test wire branched from a predetermined position of the second test wire and extended; and
calculating a first contact resistance value between the first upper pad and the first lower pad and a second contact resistance value between the second upper pad and the second lower pad based on a difference value between the first resistance value and the second resistance value.

20. The method of claim 19, wherein a length of the dummy test wire is determined such that a resistance value of the dummy test wire is equal to a resistance value of the first test wire.
